(19) United States
(12) Patent Application Publication
(10) Pub. No.: US 2020/0194606 A1
(43) Pub. Date: Jun. 18, 2020

(54) SOLAR CELL MODULE

(71) Applicant: Panasonic Corporation, Osaka (JP)

(72) Inventors: Yuya Nakamura, Osaka (JP); Haruhisa Hashimoto, Osaka (JP); Junpei Irikawa, Osaka (JP); Naoto Imada, Osaka (JP); Kenichi Maki, Osaka (JP); Takeshi Nishiwaki, Osaka (JP); Hitomi Ichinose, Osaka (JP)

(73) Assignee: Panasonic Corporation, Osaka (JP)

(21) Appl. No.: 16/708,829

(22) Filed: Dec. 10, 2019

(30) Foreign Application Priority Data
Dec. 14, 2018 (JP) 2018-234028
Sep. 10, 2019 (JP) 2019-164207

(51) Int. Cl. H01L 31/05; H01L 31/0224; H01L 31/048

(52) U.S. Cl. CPC H01L 31/0512; H01L 31/048; H01L 31/022466

(57) ABSTRACT

A solar cell module includes a plurality of solar cells arranged to be aligned along a first direction, a plurality of wiring materials configured to connect the plurality of solar cells, a plurality of first transparent members disposed individually on respective light receiving surface sides of the plurality of solar cells and bonded to the plurality of wiring materials, and a plurality of second transparent members disposed individually on respective rear surface sides of the plurality of solar cells, the rear surface sides being opposite to the light receiving surface sides, and bonded to the plurality of wiring materials.

### CROSS REFERENCE TO RELATED APPLICATION

The entire disclosure of Japanese Patent Applications No. 2018-234028 filed on Dec. 14, 2018 and No. 2019-164207 filed on Sep. 10, 2019 including, the specification, claims, drawings, and abstract is incorporated herein by reference in its entirety.

### TECHNICAL FIELD

The present invention relates to a solar cell module and more particularly to a solar cell module including a plurality of solar cells.

### BACKGROUND

In a solar cell module, a plurality of solar cells are sealed in between a front protecting member and a rear protecting member by a transparent encapsulant. The plurality of solar cells are disposed into a matrix configuration, and two solar cells lying adjacent to each other along one direction are coupled together by an interconnector. In order to facilitate fabrication of a solar cell module, there may be a situation where a wire film in which two transparent members are connected by a plurality of wires is used. In the case where the wire film is used in a solar cell module, the two transparent members are affixed to corresponding, solar cells that lie adjacent thereto, and the wires are used as wiring materials (for example, refer to Japanese Unexamined Patent Application Publication No. 2016-175020).

In the conventional solar cell module, vapor may infiltrate an interior of the solar cell module from the rear protecting member that protects a rear surface of the solar cell module that is disposed opposite to a light receiving surface thereof. Here, in the case where, for example, ethylene-vinyl acetate copolymer (EVA) is used as the transparent encapsulant, the vapor that has infiltrated the interior of the solar cell module may chemically react with the transparent encapsulant, producing a chemical component within the solar cell module. Then, in the solar cells, in the case where the resulting chemical component adheres, in particular, to a transparent conductive layer on the front surface of the solar cell, there is a possibility that the electric output of the solar cell is reduced.

### SUMMARY

### Technical Problem

The present invention has been made in view of these circumstances, and an advantage of the present invention is to provide a technique to improve the resistance to humidity of a solar cell module by improving the selectivity of a filler material.

### Solution to Problem

With a view to solving the problem, according to an aspect of the present disclosure, there is provided a solar cell module including a plurality of solar cells arranged to be aligned along, a first direction, a plurality of wiring materials configured to connect the plurality of solar cells, a plurality of first transparent members disposed individually on respective light receiving surface sides of the plurality of solar cells and bonded to the plurality of wiring materials, and a plurality of second transparent members disposed individually on respective rear surface sides of the plurality of solar cells, the rear surface sides being opposite to the light receiving surface sides, and bonded to the plurality of wiring materials, and in the solar cell module, in the plurality of first transparent members and the plurality of second transparent members, the first transparent member and the second transparent member that face each other hold one solar cell therebetween, the plurality of solar cells are also arranged to be aligned along a second direction that intersects the first direction, and the first transparent member is configured so that a length in the second direction is equal to or longer than a length of the solar cell that extends in the second direction.

According to another aspect of the present disclosure, there is provided a solar cell module including a plurality of solar cells arranged to be aligned along a first direction, a plurality of wiring materials configured to connect the plurality of solar cells, a plurality of first transparent members disposed individually on respective light receiving surface sides of the plurality of solar cells and bonded to the plurality of wiring materials, and a plurality of second transparent members disposed individually on respective rear surface sides of the plurality of solar cells, the rear surface sides being opposite to the light receiving surface sides, and bonded to the plurality of wiring materials, and in the solar cell module, in the plurality of first transparent members and the plurality of second transparent members, the first transparent member and the second transparent member that face each other hold one solar cell therebetween, the plurality of solar cells are also arranged to be aligned along a second direction that intersects the first direction, and the first transparent member is configured so that a length in the second direction is equal to or longer than a length of the solar cell that extends in the second direction, and a length in the first direction is equal to or shorter than a length of the solar cell that extends in the first direction.

### Advantageous Effect of Invention

According to the present invention, there can be provided a technique that can improve the resistance to humidity of the solar cell module by improving the selectivity of the filler material.

### BRIEF OF DESCRIPTION OF DRAWINGS

The figures depict one or more implementations in accordance with the present teachings, by way of example only, not by way of limitations. In the figures, like reference numerals refer to the same or similar elements.

Embodiments of the present disclosure will be described based on the following figures, wherein:

FIG. 1 is a plan view showing the structure of a solar cell module according to Embodiment 1 of the present invention;

FIG. 2 is a cross-sectional view showing the structure of the solar cell module of FIG. 1;

FIG. 3 is a perspective view of a film that is used in the solar cell module of FIG. 1;

FIGS. 4A is cross-sectional views showing the structure of the solar cell module of FIG. 1;

FIGS. 4B is cross-sectional views showing the structure of the solar cell module of FIG. 1;

FIG. 5 is a cross-sectional view showing the structure of a solar cell module according to Embodiment 2 of the present invention;

FIG. 6 is a perspective view of a film that is used in the solar cell module of FIG. 5;

FIG. 7 is a plan view showing part of a solar cell module according to Embodiment 3;

FIG. 8 is a cross sectional view taken along a line A-A in FIG. 7;

FIG. 9 is an enlarged view of a portion B in FIG. 7;

FIG. 10 is a view showing a modified example of Embodiment 3; and

FIG. 11 is a view showing a modified example of Embodiment 3.

### DESCRIPTION OF EMBODIMENTS

### Embodiment 1

The present invention will be summarized before it is described specifically. Embodiment 1 of the present disclosure relates to a solar cell module in which a plurality of solar cells is disposed into a matrix configuration. In the solar cell module, an encapsulant is disposed between a first protecting member and a second protecting member, and the plurality of solar cells are sealed in by the encapsulant. At this time, two adjacent solar cells are connected by a wire film. As described above, in the wire film, two transparent members are connected by a plurality of wires, and each transparent member is affixed to the corresponding solar cell that lies adjacent to the relevant transparent member. Since the wires function as wiring materials, a plurality of solar cells that are arranged in a direction in which the wires extend are connected by a plurality of wire films, whereby a string is formed. In other words, the wire films are used to facilitate the fabrication of solar cell modules. Here, in the case where ethylene-vinyl acetate copolymer (EVA) is used as the transparent encapsulant, vapor that has infiltrated the interior of the solar cell module may chemically react with EVA, producing an acetate component within the solar cell module. Then, in the solar cells, the more the resulting acetate component adheres, in particular, to the transparent conductive layer on the front surface of the solar cell, the greater the possible reduction in the electric output of the solar cell.

In the case where the wire film is used, in Embodiment 1 of the present disclosure, the transparent members are disposed individually on the light receiving surfaces and the rear surfaces of the solar cells to improve the resistance to humidity of the solar cell module. The transparent member is configured so that the length in the second direction that intersects the first direction in which the wires extend is equal to or longer than the length of the solar cell that extends in the second direction. Consequently, even though vapor infiltrates the interior of the solar cell module to produce an acetate component, the transparent member protects the transparent conductive layer from the acetate component, thereby preventing a reduction in power output. Then, in the present embodiment, the length in the second direction of the transparent member that is affixed to at least the light receiving surface of the solar cell is configured to be equal to or longer than the length of the solar cell that extends in the second direction. Consequently, the selectivity of a filler material is improved, thereby improving the resistance to humidity of the solar cell module. When referred to in the following description, “parallel” and “vertical” include not only being completely parallel and vertical but also being slightly off from the completely parallel and vertical states within a tolerance. In addition, “substantially” means being the same roughly within a certain range.

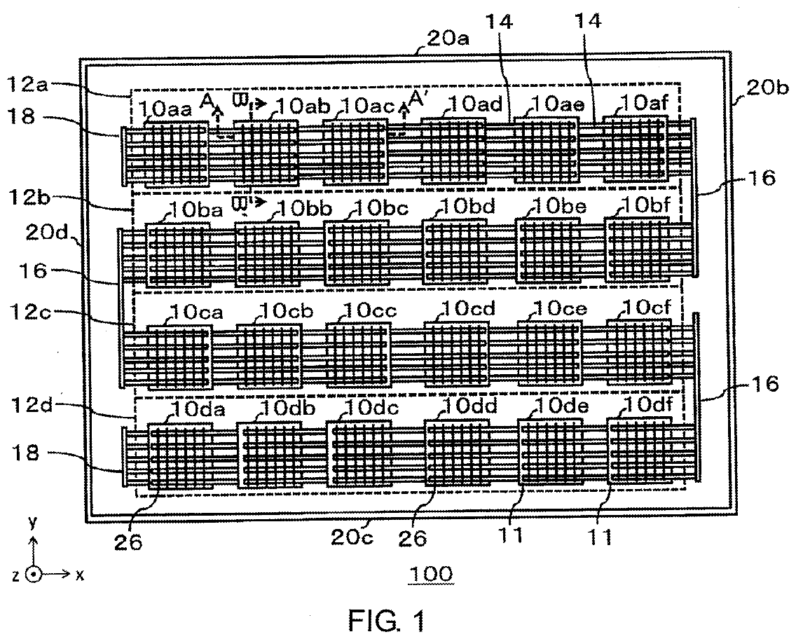

FIG. 1 is a plan view showing the structure of a solar cell module 100 according to Embodiment 1 of the present disclosure. As shown in FIG. 1, a rectangular Cartesian coordinate system formed by an x axis, a y axis, and a z axis is defined. The x axis and they axis intersect at right angles to each other within a plane of the solar cell module 100. The z axis is normal to the x axis and the y axis and extends in a thickness direction of the solar cell module 100. Additionally, positive directions of the x axis, the y axis, and the z axis are defined as directions indicated by arrows in FIG. 1, whereas negative directions thereof are defined as directions opposite to the directions indicated by the arrows. In two main surfaces that form the solar cell module 100 and that are parallel to an x-y plane, a main plane that is disposed on a side facing the positive direction of the z axis constitutes a light receiving surface, while a main plane that is disposed on a side facing the negative direction of the z axis constitutes a rear surface. Hereinafter, the side facing the positive direction of the z axis is referred to as a light receiving surface 22, and the side facing the negative direction of the z axis is referred to as a rear surface 24. As a result, FIG. 1 is a plan view of the solar cell module 100 as seen from the light receiving surface 22.

The solar cell module 100 includes an 11^{th} solar cell 10aa, . . . , a 46^{th} solar cell 10df that are generally referred to as solar cells 10, first-type wiring materials 14, second type wiring materials 16, third-type wiring materials 18, and a first frame 20a, a second frame 20b, a third frame 20c, and a fourth frame 20d that are generally referred to as frames 20.

The first frame 20a extends in the direction of the x axis, and the second frame 20b extends in the negative direction of the y axis from an end of the first frame 20a that faces the positive direction of the x axis. The third frame 20c extends in the negative direction of the x axis from an end of the second frame 20b that faces the negative direction of the y axis and the fourth frame 20d connects an end of the third frame 20c that faces the negative direction of the x axis and an end of the first frame 20a that faces the negative direction of the x axis together. The frame 20 surrounds an outer circumference of the solar cell module 100 and is formed of metal such as aluminum or the like. Here, since the first frame 20a and the third frame 20c are longer than the second frame 20b and the fourth flame 20d, the solar cell module 100 has a rectangular shape that is longer in the direction of the x axis than in the direction of the y axis. Additionally, the solar cell module 100 has a rectangular shape that is surrounded by the frame 20 on the x-y plane.

The plurality of solar cells 10 each absorb light incident thereon to generate photovoltaic power. In particular, the solar cell 10 generates photovoltaic power by absorbing light incident on the light receiving surface 22 and generates photovoltaic power by absorbing light incident on the rear surface 24. The solar cell 10 is formed from a semiconductor material such as, for example, crystalline silicon, gallium arsenide (GaAs), or indium phosphide (InP). Although no specific limitation is imposed on the structure of the solar cell 10, here, as an example, crystalline silicone and amorphous silicon are superposed on each other. In addition, although the solar cell 10 has a quadrangular shape on the x-y plane, the solar cell 10 may have other shapes such as, for example, an octagonal shape.

A first transparent conductive layer 11 and a second transparent conductive layer 13 are formed of, for example, indium oxide or zinc oxide containing a metallic dopant. As such a metallic dopant, for example, in the case of indium oxide, tungsten, tin, or the like is used, and in the case of zinc oxide, gallium, aluminum, or the like is used. The first transparent conductive layer 11 and the second transparent conductive layer 13 may contain a crystal. In other words, the first transparent conductive layer 11 and the second transparent conductive layer 13 may be formed of a polycrystalline layer or a monocrystalline layer of indium oxide or zinc oxide that contains a metallic dopant. In addition, the first transparent conductive layer 11 and the second transparent conductive layer 13 may be formed of indium oxide or zinc oxide that does not contain a metallic dopant but contains hydrogen.

The first transparent conductive layer 11 is formed as part of the light receiving surface 22 of the solar cell 10, and the second transparent conductive layer 13 is formed as part of the rear surface 24 of the solar cell 10. No specific limitation is imposed on the structures of the first and second transparent conductive layers. Here, as an example, the first transparent conductive layer 11 has the same shape as that of the light receiving surface 22 of the solar cell 10, and the second transparent conductive layer 13 has the same shape as that of the rear surface 24 of the solar cell 10. The solar cell module 100 includes a plurality of finger electrodes 26 on each of the light receiving surface 22 and the rear surface 24 of solar cell 10, and these finger electrodes 26 extend parallel to each other in the direction of the y axis. The number of finger electrodes 26 provided on each of the light receiving surface 22 and the rear surface 24 of the solar cell 10 is not limited to “6”. In the case where the solar cell 10 includes an amorphous silicon layer (not shown), the first transparent conductive layer 11 and the second transparent conductive layer 13 are preferably provided.

The plurality of solar cells 10 are arranged into a matrix configuration on the x-y plane. Here, six solar cells 10 are aligned in the direction of the x axis. The six solar cells 10 that are disposed to be aligned in the direction of the x axis are connected in series by the first-type wiring materials 14 to thereby forum one string 12. For example, when the 11^{th} solar cell 10aa, the 12^{th} solar cell 10ab, . . . , and a 16^{th} solar cell 10af are connected together, a first string 12a is formed. Additionally, strings 12 are formed similarly from a second string 12b to a fourth string 12d. As a result, four strings 12 are aligned parallel to one another in the direction of the y axis. In this way, the number of solar cells 10 that are aligned in the direction of the x axis is greater than the number of solar cells 10 that are aligned in the direction of the y axis. When the direction of the x axis is referred to as a “first direction”, the direction of the y axis is referred to as a “second direction”. The number of solar cells 10 that are included in one string 12 is not limited to “6”, and the number of strings 12 is also not limited to “4”.

In order to form the string 12, the first-type wiring materials 14 connect the finger electrodes 26 provided on a surface of the light receiving surface 22 of one of the solar cells 10 lying adjacent to each other in the direction of the x axis and the finger electrodes 26 provided on a surface of the rear surface 24 of the other of the adjacent solar cells 10. For example, five first-type wiring materials 14 for connecting the 11^{th} solar cell 10aa and the 12^{th} solar cell 10ab that lie adjacent to each other electrically connect the finger electrodes 26 on the rear surface 24 of the 11^{th} solar cell 10aa and the finger electrodes 26 on the light receiving surface 22 of the 12^{th} solar cell 10ab. The number of first-type wiring materials 14 is not limited to “5”. The first-type wiring materials 14 correspond to the wires described above. The connection of the first-type wiring materials 14 with the solar cells 10 will be described later.

The second-type wiring material 16 extends in the direction of the y axis to electrically connect the two strings 12 that lie adjacent to each other. For example, the 16^{th} solar cell 10af situated at an end of the first string 12a that faces the positive direction of the x axis and a 26^{th} solar cell 10bf situated at an end of the second string 12b that faces the positive direction of the x axis are electrically connected by the second-type wiring material 16. Further, the second string 12b and a third string 12c are electrically connected at ends thereof that face the negative direction of the x axis by the second-type wiring material 16. Then, the third string 12c and the fourth string 12d are electrically connected at ends thereof that face the positive direction of the x axis by the second-type wiring material 16. As a result, the plurality of strings 12 are connected in series by the second-types wiring material 16.

The second-type wiring material 16 is not connected to the 11^{th} solar cell 10aa at an end of the first string 12a that faces the negative direction of the x axis, and instead, the third-type wiring material 18 is connected to the 11^{th} solar cell 10aa. A take-out wiring material, not shown, is connected to the third-type wiring material 18. The take-out wiring material constitutes a wiring material configured to take out electric power generated in the plurality of solar cells 10 to the outside of the solar cell module 100. Another third-type wiring material 18 is also connected to a 41^{st} solar cell 10da at an end of a fourth string 12d that faces the negative direction of the x axis.

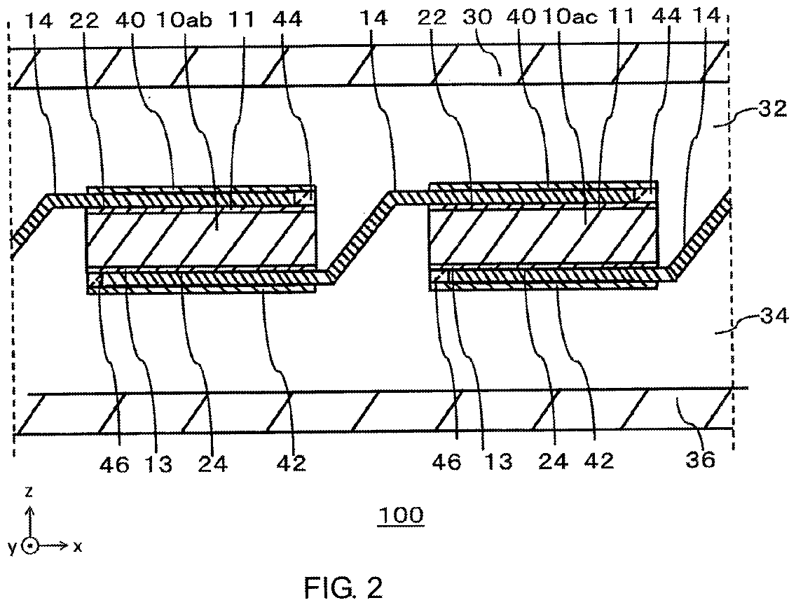

FIG. 2 is a cross-sectional view showing the structure of the solar cell module 100 and taken along the x axis and is more particularly a cross-sectional view taken along a line A-A′ in FIG. 1. The solar cell module 100 includes the 12^{th} solar cell 10ab, a 13^{th} solar cell 10ac, the first transparent conductive layer 11, the second transparent conductive layer 13, the first-type wiring materials 14, a first protecting member 30, a first encapsulant 32, a second encapsulant 34, a second protecting member 36, a first transparent member 40, a second transparent member 42, a first adhesive 44, and a second adhesive 46. In FIG. 2, an upper side corresponds to the light receiving surface 22, and a lower side corresponds to the rear surface 24.

The first protecting member 30 is disposed on a side of the solar cell 10 that constitutes the light receiving surface 22 to protect a surface of the solar cell module 100. Glass having light transmission properties and water cut-off properties, light transmitting plastic, or the like is used for the first protecting member 30. The first protecting member 30 enhances the mechanical strength of the solar cell module 100.

The first encapsulant 32 is superposed on a rear surface side of the first protecting member 30. The first encapsulant 32 is disposed between the first protecting member 30 and the solar cell 10 to bond them together. In place of EVA, for example, a thermoplastic resin such as a resin film of polyolefin, polyvinyl butyral (PVB), polyimide, or the like having a lower softening temperature than the first protecting member 30 and the second protecting member 36 is used as the first encapsulant 32. A thermosetting resin may also be used for the same purpose. Here, even though a thermoplastic resin or a thermosetting resin other than EVA is used as the first encapsulant 32 to thereby generate a chemical component that differs from the acetate component, a similar working effect can be obtained. The first encapsulant 32 is formed by a sheet material having light transmission properties and having a surface that has substantially the same dimensions as the x-y plane on the first protecting member 30.

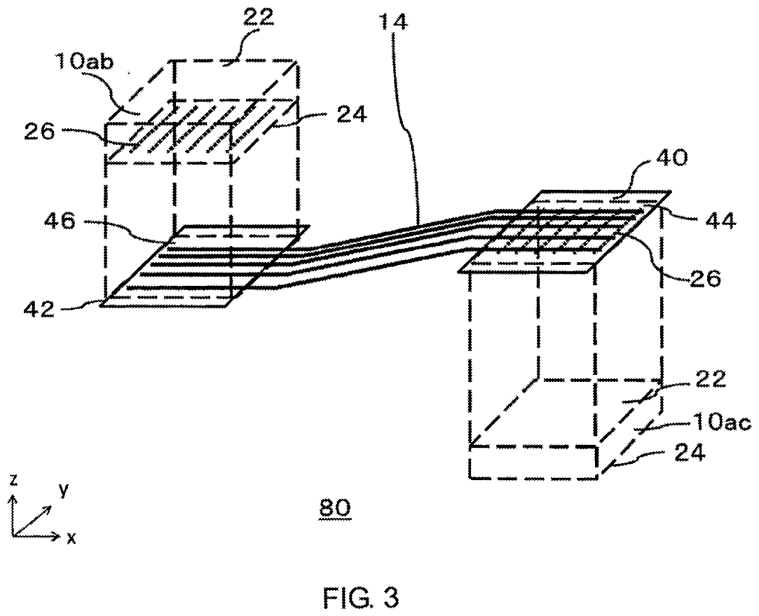

The 12^{th} solar cell 10ab and the 13^{th} solar cell 10ac are superposed on the rear surface side of the first protecting member 30. The solar cell 10 is disposed in such a manner that the light receiving surface 22 is oriented towards the positive direction of the z axis, while the rear surface 24 is oriented towards the negative direction of the z axis. When the light receiving surface 22 is referred to as a “first surface”, the rear surface 24 is referred to as a “second surface”. The first-type wiring materials 14, the first adhesive 44, and the first transparent member 40 are disposed on the, light receiving surface 22 of the solar cell 10, and the first transparent member 40 is affixed in such a manner as to cover the first transparent conductive layer 11 of the light receiving surface 22. Then, the first-type wiring materials 14, the second adhesive 46, and the second transparent member 42 are disposed on the rear surface 24 of the solar cell 10, and the second transparent member 42 is affixed in such a manner as to cover the second transparent conductive layer 13 of the rear surface 24. Here, FIG. 3 is used to describe the arrangement of these constituent members on the solar cell 10.

FIG. 3 is a perspective view of a resin sheet 80 that is used in the solar cell module 100. The resin sheet 80 includes the first-type wiring materials 14, the first transparent member 40, the second transparent member 42, the first adhesive 11, and the second adhesive 46. The resin sheet 80 corresponds to the wire film described above.

The first transparent member 40 is disposed in such a manner as to cover the first transparent conductive layer 11 of the light receiving surface 22 of one of the two solar cells 10 lying adjacent to each other; for example, the 13th solar cell 10ac. The first transparent member 40 is formed of a transparent resin film made from, for example, polyethylene terephthalate (PET). The first adhesive 44 is disposed on a surface of the first transparent member 40 that faces the 13^{th} solar cell 10ac, and the plurality of first-type wiring materials 14 are disposed on the first adhesive 14. The first adhesive 44 can bond the light receiving surface 22 of the 13^{th} solar cell 10ac to the first transparent member 40. For example, polyolefin is used for the first adhesive 11. Lengths of the first transparent member 40 and the first adhesive 44 extending in the direction of the x axis are substantially equal to the length of the solar cell 10. Then, lengths of the first transparent member 40 and the first adhesive 44 extending in the direction of the y axis are made equal to or longer than the length of the solar cell 10.

The second transparent member 42 is disposed in such a manner as to cover the second transparent conductive layer 13 of the rear surface 24 of the other of the two solar cells 10 lying adjacent to each other; for example, the 12^{th} solar cell 10ab. As with the first transparent member 40, the second transparent member 42 is formed of a transparent resin film made from, for example, polyethylene terephthalate (PET). The second adhesive 46 is disposed on a surface of the second transparent member 42 that faces the 12^{th} solar cell 10ab, and the plurality of first-type wiring materials 14 are disposed on the second adhesive 46. The second adhesive 46 can bond the rear surface 24 of the 12^{th} solar cell 10ab to the second transparent member 42. For example, polyolefin is also used for the second adhesive 46. Lengths of the second transparent member 42 and the second adhesive 46 extending in the direction of the x axis are substantially equal to the length of the solar cell 10. Then, lengths of the second transparent member 42 and the second adhesive 46 extending in the direction of the y axis are made equal to or longer than the length of the solar cell 10.

The resin sheet 80 configured in this way is fabricated in advance separately from the fabrication of the solar cell module 100. In fabricating the solar cell module 100, the first adhesive 44 is bonded to the light receiving surface 22 of the 13^{th} solar cell 10ac, and the second adhesive 46 is bonded to the rear surface 24 of the 12^{th} solar cell 10ab. As a result of the adhesives being bonded in this way, the first-type wiring materials 14 electrically connect the finger electrodes 26 on the light receiving surface 22 of the 13^{th} solar cell 10ac and the finger electrodes 26 on the rear surface 24 of the 12^{th} solar cell 10ab. FIG. 2 is referred to again.

The first transparent members 40 and the second transparent members 42 are disposed similarly on the other solar cells 10, whereby the strings 12 shown in FIG. 1 are formed. The second encapsulant 34 is superposed on a rear surface side of the first encapsulant 32. The second encapsulant 34 seals in the pluralities of solar cells 10, first-type wiring materials 14, second-type wiring materials 16, third-type wiring materials 18, first transparent members 40, second transparent members 42, and the like between the first encapsulant 32 and itself. The same material as used for the first encapsulant 32 can be used for the second encapsulant 34.

The second protecting member 36 is superposed on a rear surface side of the second encapsulant 34 in such a manner as to face the first protecting member 30. The second protecting member 36 protects a rear surface side of the solar cell module 100. For the second protecting member 36, a resin film formed from PET, polytetrafluoroethylene (PTFE) or the like is used as a back sheet. Alternatively, glass having light transmission properties and water cut-off properties, light transmitting plastic, or the like is used for the same purpose.

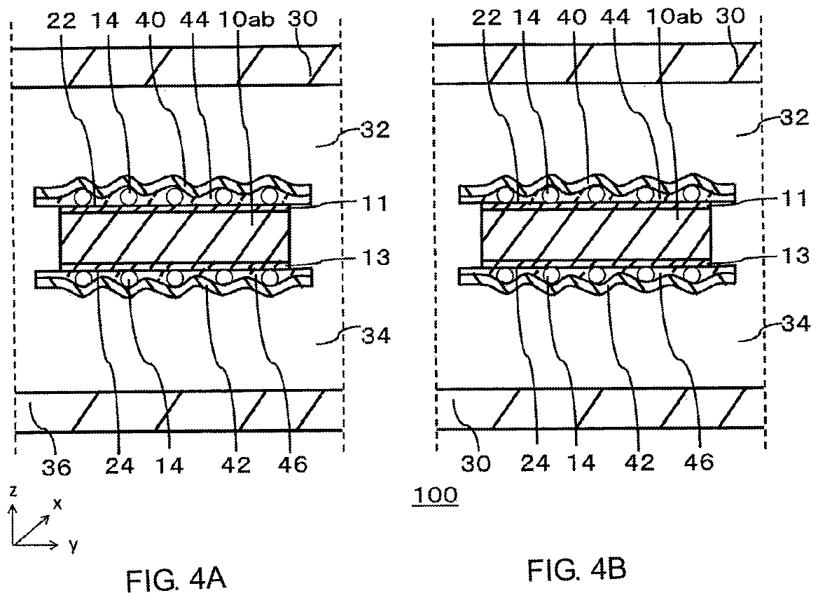

FIGS. 4A and 4B are cross-sectional views taken along the y axis which show the structure of the solar cell module 100 and are more particularly cross-sectional views taken along a line B-B′ in FIG. 1. FIG. 4A shows the solar cell module 100 in which the back sheet is used as the second protecting member 36, and FIG. 4B shows the solar cell module 100 in which glass, light transmitting plastic, or the like is used as the second protecting member 36 as in the first protecting member 30. The solar cell module 100 includes the 12^{th} solar cell 10ab, the first transparent conductive layer 11, the second transparent conductive layer 13, the first-type wiring materials 14, the first protecting member 30, the first encapsulant 32, the second encapsulant 34, the second protecting member 36, the first transparent member 40, the second transparent member 42, the first adhesive 44, and the second adhesive 46. In FIG. 4, an upper side corresponds to a light receiving surface side, while a lower side corresponds to a rear surface side. Here, in order to clarify the description, in the configuration of the solar cell module 100, the description of a configuration near the light receiving surface 22 is omitted, and a configuration near the rear surface 24 of the solar cell module 100 will mainly be described.

In FIG. 4A, the back sheet protects the rear surface side of the solar cell module 100 as the second protecting member 36. A resin film formed from PET, polytetrafluoroethylene (PTFE), or the like is used as the back sheet. In FIG. 4B, glass having the light transmission properties and water cut-off properties, light transmission plastic or the like is used as the second protecting member 36. Thus, as with the first protecting member 30, glass having the light transmission properties and water cut-off properties, light transmission plastic, or the like is used as the second protecting member 36.

Hereinafter, a fabrication method of the solar cell module 100 will be described. Firstly, the resin, sheets 80 are prepared. The first transparent member 40 of the resin sheet 80 is superposed on one of the two adjacent solar cells 10, and the second transparent member 42 of the resin sheet 80 is superposed on the other of the two adjacent solar cells 10. By repeating this process on the remaining pairs of solar cells 10 the string 12 is produced. The first protecting member 30, the first encapsulant 32, the strings 12, the second encapsulant 34, and the second protecting member 36 are sequentially superposed on one another from the positive direction to the negative direction of the z axis, whereby a laminated body is produced. Following this, a laminate cure process is performed on the laminated body. In this process, air is drawn out from the laminated body, and the laminated body is heated and pressurized, whereby the laminated body is integrated further. In a vacuum lamination in the laminate cure process, the temperature is set at about 110 to 170° C. Further, a terminal box is attached to the second protecting member 36 with an adhesive.

According to the present embodiment, at least the first transparent member 40 and the first adhesive 44 that are disposed on the light receiving surface 22 of the solar cell 10 are configured so that lengths in the second direction that intersects the first direction that is the direction in which the first-type wiring materials 14 extend are equal to or longer than a length in the second direction of the solar cell 10. In addition, the first transparent member 40, the first adhesive 44, the second transparent member 42, and the second adhesive 46 may be configured so that lengths in the second direction are equal to or longer than the length in the second direction of the solar cell 10. At least the first transparent member 40 and the first adhesive 44 are configured so that the lengths in the second direction are equal to or longer than the length in the second direction of the solar cell 10, whereby even though vapor and EVA in the solar cell module chemically react with each other to produce an acetate component, the first transparent member 40 and the first adhesive 44 can protect the first transparent conductive layer 11 from the acetate component. Consequently, since the first transparent member 40 and the first adhesive 44 can prevent the acetate component from adhering to the first transparent conductive layer 11, a reduction in power output can be prevented.

Also, in the case where the back sheet is used as the second protecting member 36, or glass having the light transmission properties and water cut-off properties.,light transmission plastic, or the like is used as the second protecting member 36, at least the first transparent member 40 and the first adhesive 44 are configured so that the lengths in the second direction are equal to or longer than the length in the second direction of the solar cell 10 and are configured in such a manner as to cover the first transparent conductive layer 11. Consequently, since the first transparent member 40 and the first adhesive 44 can protect the first transparent conductive layer 11 from the acetate component, not only is the selectivity of a filler material improved, but also the resistance to humidity of the solar cell module 100 is improved.

An aspect of the present disclosure is summarized as below. The solar cell module 100 includes the plurality of solar cells 10 that are disposed to be aligned in the first direction, the plurality of first-type wiring materials 14 that connect the plurality of solar cells 10 together, the first transparent members 40 that are disposed individually on the respective light receiving surfaces 22 of the plurality of solar cells 10 and that are bonded to the plurality of first-type wiring materials 14, and the second transparent members 42 that are disposed on the rear surfaces 24 of the plurality of solar cells 10, which lie opposite to the light receiving surfaces 22, and that are bonded to the plurality of first-type wiring materials 14. In the plurality of first transparent members 40 and the plurality of second transparent members 42, the first transparent member 40 and the second transparent member 42 that face each other hold one solar cell 10 therebetween, and the plurality of solar cells 10 are also aligned in the second direction that intersects the first direction. At least the first transparent member 40 and the first adhesive 44 are configured so that the lengths in the second direction are equal to or longer than the length in the second direction of the solar cell 10.

The solar cell module 100 includes further the first protecting member 30 that is provided on a light receiving surface side of the first transparent member 40, the first encapsulant 32 that is provided on the light receiving surface side of the first transparent member 40 and between the first transparent member 40 and the first encapsulant 32, the second protecting member 36 that is provided on a rear surface side of the second transparent member 42, and the second encapsulant 34 that is provided on the rear surface side of the second transparent member 42 and between the second transparent member 42 and the second protecting member 36. The softening temperatures of the first encapsulant 32 and the second encapsulant 34 are lower than those of the first protecting member 30 and the second protecting member 36.

The first transparent member 40 and the first adhesive 44 may be such that lengths in the first direction that is the direction in which the first-type wiring materials 14 extend are equal to a length in the first direction of the solar cell 10.

Glass having the light transmission properties and water cut-off properties, light transmission plastic, or the like may be used for at least one of the first protecting member 30 and the second protecting member 36.

### Embodiment 2

Next, Embodiment 2 of the present disclosure will be described. As with Embodiment 1, Embodiment 2 of the present disclosure relates to a solar cell module 100 including strings 12 formed by affixing resin sheets 80 to solar cells 10. In Embodiment 1 of the present disclosure, at least the first transparent member 40 and the first adhesive 44 are configured so that the lengths in the second direction that intersects the first direction that is the direction in which the first-type wiring materials 14 extend are equal to or longer than the length in the second direction of the solar cell 10. On the other hand, in Embodiment 2, at least a first transparent member 40a and a first adhesive 44 are configured so that lengths in a second direction are equal to or longer than a length in the second direction of a solar cell 10 and that lengths in a first direction are equal to or shorter than a length in the first direction of the solar cell 10. The solar cell module 100 according to Embodiment 2 of this present disclosure has the same configuration as that shown in FIGS. 1 and 4. Here, a difference from Embodiment 1 will mainly be described.

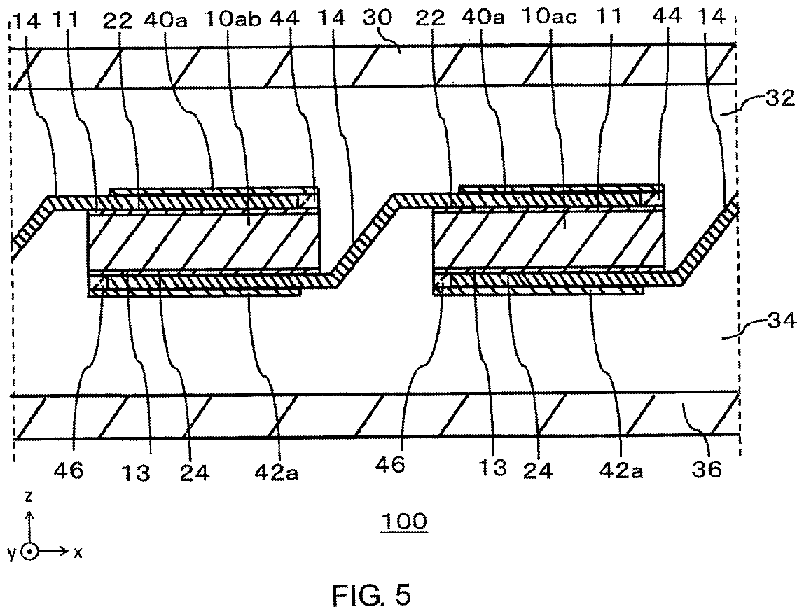

FIG. 5 is a cross-sectional view showing the structure of the solar cell module 100 according to Embodiment 2 of the present disclosure. Similar to FIG. 2 showing Embodiment 1 of the present disclosure, the solar cell module 100 includes a 12^{th} solar cell 10ab, a 13^{th} solar cell 10ac, a first transparent conductive layer 11, a second transparent conductive layer 13, first-type wiring materials 14, a first protecting member 30, a first encapsulant 32, a second encapsulant 34, a second protecting member 36, the first adhesive 44, and a second adhesive 46.

A first transparent member 40a is disposed in such a manner as to cover the first transparent conductive layer 11 on a light receiving surface 22 of one of two adjacent solar cells 10; for example, the 13^{th} solar cell 10ac. As with the first transparent member 40, the first transparent member 40a is made up, for example, of a transparent resin film made of polyethylene terephthalate (PET) or the like. The first transparent member 40a and the first adhesive 44 are configured so that lengths in a direction x that is a direction in which the first-type wiring materials 14 extend are equal to or shorter than a length in the direction x of the solar cell 10. Additionally, the first transparent member 40a and the first adhesive 44 are configured so that lengths in a direction y are equal to or longer than a length in the direction y of the solar cell 10.

A second transparent member 42a is disposed in such a manner as to cover the second transparent conductive layer 13 on a rear surface 24 of the other of the two adjacent solar cells 10 for example, the 12^{th} solar cell 10ab. As with the second transparent member 42, the second transparent member 42a is made up, for example, of a transparent resin film made of PET or the like. The second transparent member 42a and the second adhesive 46 are configured so that lengths in the, direction x that is the direction in which the first-type wiring materials 14 extend are equal to or shorter than a length in the direction x of the solar cell 10. Additionally, the second transparent member 42a and the second adhesive 46 are configured so that lengths in the direction y are equal to or longer than a length in the direction y of the solar cell 10.

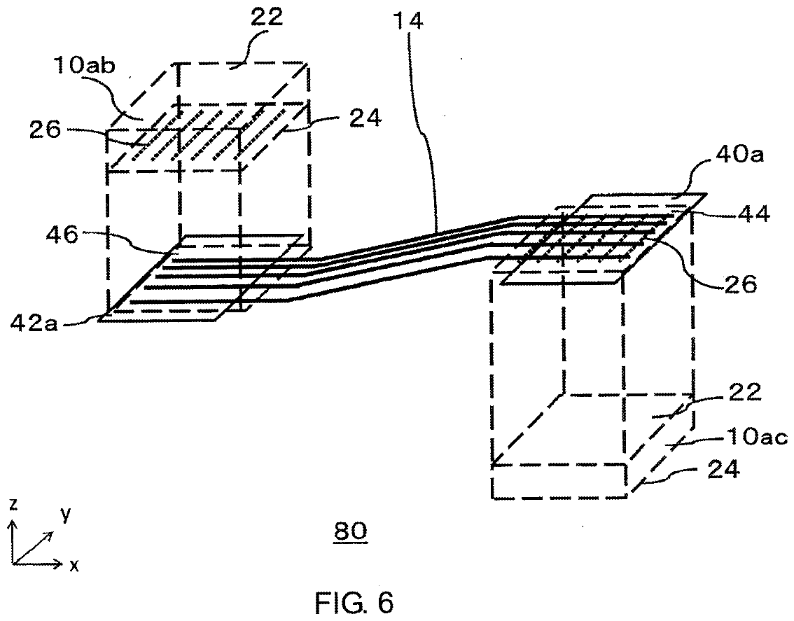

FIG. 6 is a perspective view of a resin sheet 80 used in the solar cell module 100 according to Embodiment 2 of the present disclosure. As with FIG. 3 showing Embodiment 1 of the present disclosure, the resin sheet 80 includes the first-type wiring materials 14, the first adhesive 44, and the second adhesive 46.

The first transparent member 40a is disposed in such a manner as to cover the first transparent conductive layer 11 on the light receiving surface 22 of one of the two adjacent solar cells 10; for example, the 13^{th} solar cell 10ac. The first transparent member 40a is made up, for example, of a transparent resin film made of polyethylene terephthalate (PET) or the like. The first transparent member 40a and the first adhesive 44 are configured so that the lengths in the direction x that is the direction in which the first-type wiring materials 14 extend are equal to or shorter than the length in the direction x of the solar cell 10. Additionally, the first transparent member 40a and the first adhesive 44 are configured so that the lengths in the direction y are equal to or longer than the length in the direction y of the solar cell 10.

The second transparent member 42a is disposed in such a manner as to cover the first transparent conductive layer 13 on the rear surface 24 of the other of the two adjacent solar cells 10; for example, the 12^{th} solar cell 10ab. The second transparent member 42a is made up, for example, of a transparent resin film made of polyethylene terephthalate (PET) or the like. The second transparent member 42a and the second adhesive 46 are configured so that lengths in the direction x that is the direction in which the first-type wiring materials 14 extend are equal to or shorter than the length in the direction x of the solar cell 10. Additionally, the second transparent member 42a and the second adhesive 46 are configured so that lengths in the direction y are equal to or longer than the length in the direction y of the solar cell 10.

According to the present embodiment, at least the first transparent r member 40a and the first adhesive 44 that are disposed on the solar cell 10 are configured so that the lengths in the first direction that is the direction in which the first-type wiring materials 14 extend are equal to or shorter than the length in the first direction of the solar cell 10 and that the lengths in the second direction that intersects the first direction are equal to or longer than the length in the second direction of the solar cell 10. The first transparent member 40a, the first adhesive 44, the second transparent member 42a, and the second adhesive 46 may be configured so that the lengths in the direction x that is the direction in which the first-type wiling materials 14 extend are equal to or shorter than the length in the direction x of the solar cell 10 and that the lengths in the direction y are equal to or longer than the length in the direction y of the solar cell 10. The first encapsulant 32 and the second encapsulant 34 are caused to extend or contract as the temperature increases or decreases. End portions facing the negative direction of the x axis of the first transparent member 40a and the first adhesive 44 that are bonded to the first-type wiring materials 14 that are connected to the solar cells 10ac are situated further in the positive direction of the x axis than an end portion facing the negative direction of the x axis of the solar cell 10ac. As a result, the first-type wiring materials 14 that are situated in an area between the solar cell 10ab and the solar cell 10ac can be prevented from being disconnected, which would otherwise be true as a result of extension or contraction of the first encapsulant 32 and the second encapsulant 34. In the present embodiment, end portions facing the positive direction of the x axis of the first transparent member 40a and the first adhesive 44 that are provided on the light receiving surface side of the solar cell 10ac are made to substantially coincide with an end portion facing the positive direction of the x axis of the solar cell 10ac. However, the present invention is not limited to the configuration of the present embodiment. For example, the end portions facing the positive direction of the x axis of the first transparent member 40a and the first adhesive 44 can be made to be situated further in the negative direction of the x axis than the end portion facing the positive direction of the x axis of the solar cell 10ac.

An aspect of the present disclosure is summarized as below. The solar cell module 100 includes the plurality of solar cells 10 that are disposed so as to be aligned in the first direction the plurality of first-type wiring materials 14 that connect the plurality of solar cells 10 together, the first transparent members 40a that are disposed individually on the respective light receiving surfaces 22 of the plurality of solar cells 10 and that are bonded to the plurality of first-type wiring materials 14, and the second transparent members 42a that are disposed individually on the rear surfaces 24, lying opposite to the corresponding light receiving surfaces 22, of the plurality of solar cells 10 and that are bonded to the plurality of first-type wiring materials 14. In the plurality of first transparent members 40a and the plurality of second transparent members 42a, the first transparent member 40a and the second transparent member 42a that face each other hold one solar cell 10 therebetween, and the plurality of solar cells 10 are also aligned in the second direction that intersects the first direction. At least the first transparent member 40a and the first adhesive 44 are configured so that the lengths in the second direction are equal to or longer than the length in the second direction of the solar cell 10 and that the lengths in the first direction are equal to or shorter than the length in the first direction of the solar cell 10.

### Embodiment 3

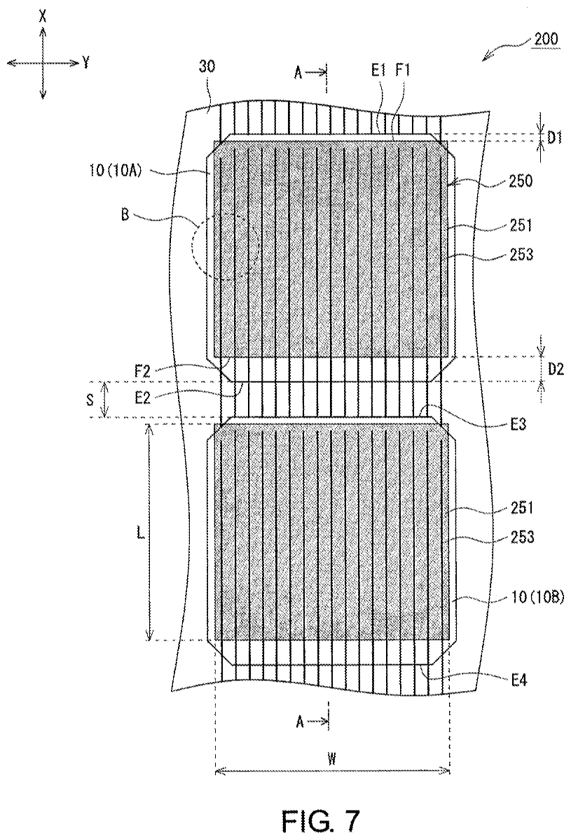

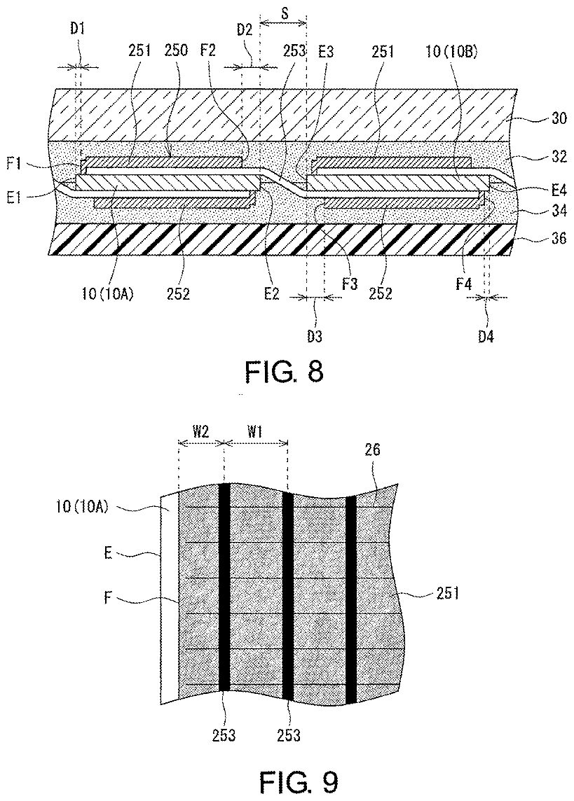

Hereinafter, referring to FIGS. 7 to 11, a solar cell module 200 according to Embodiment 3 will be described in detail. FIG. 7 is a plan view showing part of the solar cell module 200. FIG. 8 is a cross-sectional view taken along a line A-A in FIG. 7, and FIG. 9 is an enlarged view of a portion B in FIG. 7.

As illustrated in FIGS. 7 and 8, the solar cell module 200 is similar to the embodiments that have been described heretofore in that the solar cell module 200 includes the plurality of solar cells 10, a first protecting member 30, and a second protecting member 36. In addition, a first encapsulant 32 is disposed between the first protecting member 30 and solar cells 10, and a second encapsulant 34 is disposed between the solar cells 10 and the second protecting member 36, whereby the solar cells 10 are sealed in. Similar to the embodiments that have beer described above, the solar cell module 200 includes wire films 250. However, the solar cell module 200 differs from the embodiments that have been described above in the configuration of a portion of the relevant film and in a joining form in which the wire film 250 is joined to the corresponding solar cell 10.

In the present embodiment, crosslinkable polyolefin may be used for the first encapsulant 32, and crosslinkable EVA may be used for the second encapsulant 34. In the case where a curable resin containing a crosslinkable component is applied to the first encapsulant 32 and the second encapsulant 34, the degree of crosslinking of the first encapsulant 32 may be set lower than the degree of crosslinking of the second encapsulant 34. The degree of crosslinking of the encapsulant can be evaluated based on a gel separation rate thereof.

In the following description, as a matter of convenience in description, one of adjacent solar cells 10 that are connected together by a wire film 250 is referred to as a “solar cell 10A”, and the other is referred to as a “solar cell 10B”. In addition, in a plan view of the solar cell module 200, a direction along a longitudinal direction of wiring materials 253 making up the wire film 250; that is, a direction in which the solar cells 10A, 10B are aligned is referred to as a “direction X”, and a direction that intersects the direction X at right angles is referred to as a “direction Y”.

Incidentally, since there is a case where the solar cell module 200 is used under such an environment where the temperature changes greatly, the solar cell module 200 preferably has superior temperature cycle properties. In the case where the temperature of the solar cell module 200 changes greatly, a gap defined between adjacent solar cells 10 changes due to an extension or a contraction of the encapsulants, leading to a risk that wiring materials 253 connecting the two solar cells 10 together are broken. As will be described in more detail below, in the solar cell module 200, the risk of breakage of the wiring materials 253 can be prevented by devising the joining form of the wire film 250 to the solar cells 10.

As with the wire films of the embodiments that have been described above, the wire film 250 is made up of a first transparent film 251 that is joined to a light receiving surface of the solar cell 10A, a second transparent film 252 that is joined to a rear surface of the solar cell 10B, and a plurality of the wiring materials 253. The plurality of wiring materials 253 are disposed parallel to one another, and are joined to the first transparent film 251 at one longitudinal end portions thereof and to the second transparent film 252 at the other longitudinal end portions thereof. No transparent film is present at longitudinal central portions of the plurality of wiring materials 253, and hence, the first transparent film 251 and the second transparent film 252 are provided in such a manner as to define a predetermined gap at the longitudinal central portions of the wiring materials 253.

The first transparent film 251 and the second transparent film 252 each have, for example, a film-like transparent base material and a transparent adhesive layer formed on one surface of the base material. A resin film made up of a PET film that is similar to the resin film applied to the first transparent member 40 and the second transparent member 42, which are described above, is used for the base material. The adhesive layer is formed by use of an adhesive formed from polyolefin or an adhesive similar to the adhesive used for the first adhesive 44 and the second adhesive 46 that are described above. In the present embodiment, the first transparent film 251 and the second transparent film 252 are illustrated as having the adhesive layer that is formed over a whole area of the one surface of the transparent base material, but the base material and the adhesive may be supplied as separate members.

The first transparent film 251 and the second transparent film 252 each have, for example, a quadrangular shape in a plan view, and two sides of the quadrangular shape are disposed along the direction X, while the remaining two sides are disposed along the direction Y. In the example shown in FIG. 7, a length L in the direction X of the first transparent film 251 is shorter than a length in the direction X of the solar cell 10, and a length W in the direction Y of the first transparent film 251 is shorter than a length in the direction Y of the solar cell 10. In the first transparent film 251, the length W in the direction Y is made longer than the length L in the direction X, and four corners are formed at right angles.

A substantial whole of the first transparent film 251 is joined onto a light receiving surface of the solar cell 10. The solar cell 10 has, in a plan view, a substantially square shape having short oblique sides as a result of four corner portions being slightly cut obliquely. In the example shown in FIG. 7, two corner portions of the first transparent film 251 project outwardly of the light receiving surface of the solar cell 10 from the obliquely cut sides thereof. However, the corner portions of the first transparent film 251 may be cut in a similar way to the way in which the corner portions of the solar cell 10 are cut, so that the corner portions of the first transparent film 251 do not project from the light receiving surface of the solar cell 10. In addition, a substantial whole of the second transparent film 252 is joined onto the rear surface of the solar cell 10.

As shown in FIG. 9, the first transparent film 251 is joined onto the light receiving surface of the solar cell 10 with a predetermined gap defined between a cell end E and a film end F so that the first transparent film 251 does not project from the light receiving surface, at the end portion of the solar cell 10 in the direction Y. A gap W2 between the film end F and a wiring material 253 lying nearest to the film end F may be smaller than a gap W1 defined between the wiring materials 253, and the gap W2 is preferably 0.3 to 0.7 times the gap W1 and more preferably 0.5 to 0.7 times the gap W1. The gaps W1 have the same length and are greater than gaps defined between finger electrodes 26. The gap W2 may be smaller than the gap W1 and larger than the gaps defined between the finger electrodes 26.

As shown in FIGS. 7 and 8, the plurality of wiring materials 253 are bent in a thickness direction of the module at a gap S between the solar cells 10A, 10B, and are joined onto the light receiving surface of the solar cell 10A by the first transparent film 251 and onto the rear surface of the solar cell 10B by the second transparent film 252. As a result, the wiring materials 253 are connected to the finger electrodes 26 (refer to FIG. 9) on the light receiving surface side of the solar cell 10A and the finger electrodes 26 on the rear surface side of the solar cell 10B, whereby the solar cells 10A, 10B are electrically connected to each other. In general, respective bent portions of the wiring materials 253 are formed at the gap S between the solar cells 10A, 10B.

The plurality of wiring, materials 253 are disposed from the vicinity of a cell end E1 of the solar cell 10A to the vicinity of a cell end E4 of the solar cell 10B. A length of each wiring material 253 is slightly shorter than, for example, a length resulting from addition of an inter-cell distance to a total of lengths in the direction X of the solar cells 10A, 10B. The second transparent film 252 covers most of a portion of each wiring material 253 that includes a longitudinal end and that is disposed on the light receiving surface of the solar cell 10A is covered by the first transparent film 251, and most of a portion of each wiring material 253 that includes the other longitudinal end and that is disposed on the rear surface of the solar cell 10B.

Here, a cell end E1 of the solar cell 10A means an end portion that is situated opposite to a cell end E2 lying along the gap S on the x axis, and a cell end E4 of the solar cell 10B means an end portion that is situated opposite to a cell end E3 lying along the gap S on the x axis. Film ends F1 to F4 mean end portions of the first transparent film 251 and the second transparent film 252 that lie near to the cell ends E1 to E4, respectively. In the present embodiment, the cell ends E1 to E4 and the film ends F1 to F4 are all parallel to one another and extend in the direction Y.

In the solar cell module 200, a gap D2 between the cell end E2 of the solar cell 10A and the film end F2 of the first transparent film 251 is greater than a gap D1 between the cell end E1 and the film end F1. In other words, the first transparent film 251 is joined onto the light receiving surface of the solar cell 10A at a position lying closer to the cell end E1 than to the cell end E2. Then, in the portion of each wiring material 253 that is disposed on the light receiving surface of the solar cell 10A, a portion lying close to the cell end E2 is not covered by the first transparent film 251 and is not fixed to the light receiving surface by the film.

Also in relation to the second transparent film 252, a gap D3 between the cell end E3 of the solar cell 10B and the film end F3 of the second transparent film 252 is greater than a gap D4 between the cell end E4 and the film end F4. In other words, the second transparent film 252 is joined onto the rear surface of the solar cell 10B at a position lying closer to the cell end E4 than to the cell end E3. Then, in the portion of each wiring material 253 that is disposed on the rear surface of the solar cell 10B, a portion lying close to the cell end E3 is not covered by the second transparent film 252 and is not fixed to the rear surface by the film.

In the solar cell module 200, the vicinities of the bent portions of the wiling materials 253 are not fixed to the solar cells 10, whereby the wiring materials 253 are allowed to extend or contract (deform) easily and move easily as the inter-cell distances change. As a result, as compared with the case where the wiring materials 253 are fixed to the surfaces of the solar cells, the wiring materials 253 are allowed to extend or contract easily, whereby breakage of the wiring materials 253 is prevented.

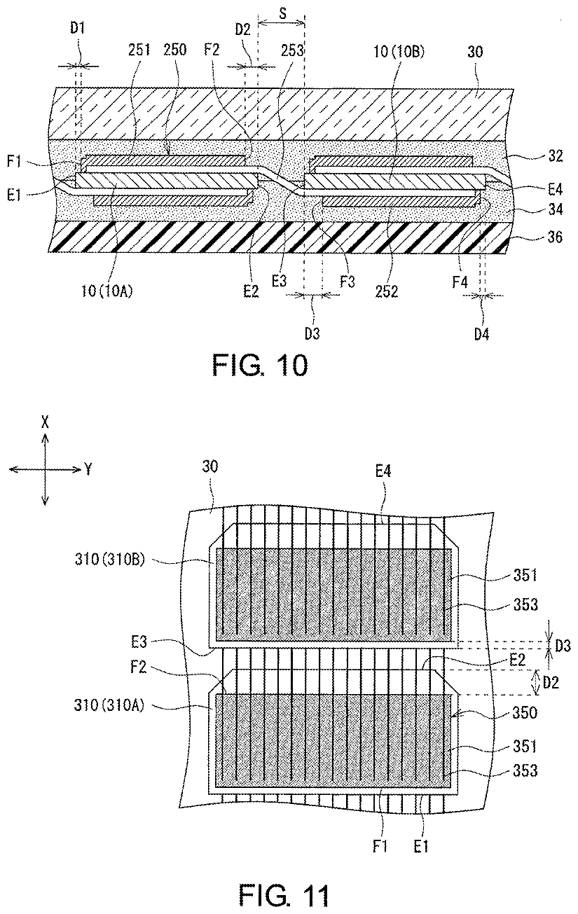

Modified examples of the solar cell module 200 are shown in FIGS. 10 and 11. A form illustrated in FIG. 10 differs from the form illustrated FIG. 8 in that the gap D3 is greater than the gap D2. In many cases, more finger electrodes 26 are formed on a rear surface of the solar cell 10 than on a light receiving surface thereof. In other words, an area of portions of the rear surface of the solar cell 10 that are covered by the electrodes is greater than an area of portions of the light receiving surface of the solar cell 10 that are covered by the electrodes. Since the area of the portions that are covered by the electrodes constituting metallic layers is great, the solar cell 10 before incorporation into the solar cell module tends to warp easily into such a state that the light receiving surface projects convexly, while the rear surface is depressed concavely. Even after the solar cell 10 is processed to be incorporated in the solar cell module, there still remains stress attempting to cause the solar cell 10 to warp towards the rear surface in the solar cell 10. Then, the gap D3 on the rear surface side where the area of the electrodes is great is set greater than the gap D2 on the light receiving surface side where the area of the electrodes is small, so that the wires are allowed to move easily when the wires come into contact with an outer circumference of the solar cell.

The reason why the configuration described above is adopted is considered as follows. When the solar cell module is seen in section, in the case where the surface of the solar cell warps in such a manner as to project convexly, the rear surface thereof warps in such a manner as to be depressed concavely, whereby the wires warp along the rear surface of the solar cell in such a manner as to project convexly towards the front surface. At this time, the wires extend downwards on the outer circumference of the solar cell. Since the wires are attached to the front surface of the adjacent solar cell, as compared with a case where the extent at which the solar cell warps on the rear surface is small, the relevant wires are bent upwards at a steep angle. In this case, by enhancing the degree of freedom in moving of the wiring materials on the rear surface side, the wires and the end portion of the solar cell are prevented from being brought into strong contact with each other, thereby reducing a possibility of breakage of the wiring materials.

The relationship between the gap D2 and the gap D3 in relation to size may be determined based on the degree of crosslinking of the encapsulants on the front surface and the rear surface. For example, in the case where the degree of crosslinking of the first encapsulant 32 is set lower than the degree of crosslinking of the second encapsulant 34, the gap D2 on the light receiving surface side may be set greater than the gap D3 on the rear surface side. Table 1 shows an experimental example in the case where the degree of crosslinking of the first encapsulant 32 is lower than the degree of crosslinking of the second encapsulant 34. When studying the degree at which the output changes as the gap D2 changes and the durability of the solar cell module against a change in the gap D3, changing the gap D2 has a greater effect on the durability of the solar cell module than does changing the gap D3. From the viewpoint of the output of the solar cell module, holding both the gap D2 and the gap D3 small is preferable, since the first-type wiring materials 14 can be kept in contact with the surfaces of the solar cells 10. Due to this, the reliability can be enhanced while maintaining the output of the solar cell module by holding the gap D3 at a constant width and expanding the gap D2 to a great width.

TABLE 1

| | | | | |
|---|---|---|---|---|
| D2 | Distance | 0.1 | 0.4 | 1.1 |
| | Magnification | — | 4 | 11 |
| D3 | Distance | 2.2 | 1.7 | 3.1 |
| | Magnification | — | 0.77 | 1.4 |
| Reliability | | Δ | ◯ | ◯◯ |

Further, the warping direction of the solar cell and the degree of crosslinking, of the encapsulants can both be taken into consideration. The embodiment illustrated in FIG. 10 constitutes an embodiment that is preferred in the case where the degree of crosslinking of the encapsulant 32 is lower than the degree of crosslinking of the encapsulant 34. However, in the case where the degree of crosslinking of the encapsulant 32 is higher than the degree of crosslinking of the encapsulant 34, the solar cell module is preferably configured so that D2>D3, and in the case where the solar cells tend to warp easily, warping of the solar cells is preferably taken into consideration. Hereinafter, an experimental example will be shown.

TABLE 2

| | Degree of | Degree of | | |
|---|---|---|---|---|
| | Crosslinking of | Crosslinking of | | Relationship |
| | Front Surface | Rear Surface | Warping | between D2 |
| | Encapsulant | Encapsulant | of Cell | and D3 |
| EXP Exam- | Low | High | Small | D2 > D3 |
| ple 1 | | | | |
| EXP Exam- | High | Low | Small | D2 < D3 |
| ple 2 | | | | |
| EXP Exam- | Low | High | Great | D2, D3 Both |
| ple 3 | | | | Great |
| EXP Exam- | High | Low | Great | D2 < D3 |
| ple 4 | | | | |

The form illustrated in FIG. 11 differs from the embodiment described above in that a solar cell module is configured by use of solar cells 310 that are made by cutting a solar cell into halves at a center in a direction X. The solar cell 310 has a substantially rectangular shape in a plan view in which a length in a direction Y is longer than a length in the direction X and two corner portions at one end in the direction X are cut obliquely. Solar cells 310A, 310B are electrically connected by a wire film 350 that includes a first transparent film 351, a second transparent film, not shown, and a plurality of wiring materials 353. In the example shown in FIG. 11, the first transparent film 351 is joined onto a light receiving surface of the solar cell 310A, and the second transparent film (not shown) is joined onto a rear surface of the solar cell 310B.

The first transparent film 351 is joined onto the light receiving surface of the solar cell 310A at a position lying closer to a cell end E1 where rectangular corner portions are formed than to a cell end E2 where the corner portions are cut obliquely. In this case, on a light receiving surface side of the solar cell 310, a gap D2 between the cell end E2 of the solar cell 310A and a film end F2 of the first transparent film 351 is greater than a gap between the cell end E1 and a film end F1. A whole of the first transparent film 351 is joined onto the light receiving surface of the solar cell 310 without projecting from the light receiving surface.

The second transparent film may be joined onto the rear surface of the solar cell 310B at a position lying closer to a cell end E3 where rectangular corner portions are formed than to a cell end E4 where corner portions are cut obliquely. In this case, a gap between the cell end E4 of the solar cell 310E and a film end F4 of the second transparent film is greater than a gap D3 between the cell end E3 and a film end F3.

In a case where a solar cell module is configured by use of the example illustrated in FIG. 11, when the degree of crosslinking of the front and rear encapsulants and the warping of the solar cell are taken into consideration, the way of connecting the plurality of solar cells 310 needs to be modified in accordance with the relationship between the gap D2 and the gap D3 in relation to size in Table 2. In the solar cells 310, since the two corner portions at the one end in the direction X are cut obliquely, the first transparent film 351 and the second transparent film are disposed in such a manner as not to overlap these corner portions. In other words, the distance between the first transparent film 351 and the cell end E4 comes to take a relatively great value. When the gap D2 is desired to be increased in consideration of this point, the same connecting form as that of the embodiment illustrated in FIG. 11 is preferably adopted. However, on the contrary, when the gap D3 is desired to be increased, the connecting form of connecting the solar cells 310 together needs to be modified. In other words, the solar cells 310 are preferably connected together by reversing vertically the solar cells 310 shown in FIG. 11 in such a manner that the obliquely cut corner portions are situated on lower sides of the corresponding solar cells 310 with respect to the figure. At this time, the positions of the first transparent film and the second transparent film may be controlled as required in such a mariner that the first and second transparent films do not project from the corresponding solar cells 310.

The present invention has been described based on the embodiments. Those skilled in the art to which the present invention pertains can understand that the embodiments are examples, that the constituent elements of the embodiments can be modified in various manners, and that the resulting modified examples fall within the scope of the present invention. Additionally, portions of the embodiments other than those characteristic of the embodiments can be combined with one another in carrying out the present invention.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell module, comprising:
a plurality of solar cells arranged to be aligned along a first direction;
at plurality of wiring materials configured to connect the plurality of solar cells;
a plurality of first transparent members disposed individually on respective light receiving surface sides of the plurality of solar cells and bonded to the plurality of wiring materials; and
a plurality of second transparent members disposed individually on respective rear surface sides of the plurality of solar cells, the rear surface sides being opposite to the light receiving surface sides, and bonded to the plurality of wiring materials, and in the solar cell module,
wherein in the plurality of first transparent members and the plurality of second transparent members, the first transparent member and the second transparent member that face each other hold the one solar cell therebetween,
wherein the plurality of solar cells are also arranged to be aligned along a second direction that intersects the first direction, and
wherein the first transparent member and the second transparent member are configured so that a length in the second direction is equal to or longer than a length of the solar cell that extends in the second direction.

2. The solar cell module according to claim 1, further comprising:
a first protecting member provided on the light receiving surface sides of the plurality of first transparent members;
a first encapsulant provided on the light receiving surface sides of the plurality of first transparent members and between the plurality of first transparent members and the first protecting member;
a second protecting member provided on the rear surface sides of the plurality of second transparent members; and
a second encapsulant provided on the rear surface sides of the plurality of second transparent members and between the plurality of second transparent members and the second protecting member,
wherein softening temperatures of the first encapsulant and the second encapsulant are lower than those of the first protecting member and the second protecting member.

3. The solar cell module according to claim 1,
wherein a length in the first direction of the first transparent member is equal to a length in the first direction of the solar cell.

4. The solar cell module according to claim 1,
wherein at least one of the first protecting member and the second protecting member has light transmission properties and water cut-off properties.

5. The solar cell module according to claim 1,
wherein the solar cell comprises transparent conductive layers on the light receiving surface and the rear surface thereof.

6. A solar cell module, comprising:
a plurality of solar cells arranged to be aligned along a first direction;
a plurality of wiling materials configured to connect the plurality of solar cells;
a plurality of first transparent members disposed individually on respective light receiving surface sides of the plurality of solar cells and bonded to the plurality of wiring materials; and
a plurality of second transparent members disposed individually on respective rear surface sides of the plurality of solar cells, the rear surface sides being opposite to the light receiving surface sides and bonded to the plurality of wiring materials,
wherein, in the plurality of first transparent members and the plurality of second transparent members, the first transparent member and the second transparent member that face each other hold the one solar cell therebetween,
wherein the plurality of solar cells are also arranged to be aligned along a second direction that intersects the first direction, and
wherein the first transparent member and the second transparent member are configured so that a length in the second direction is equal to or longer than a length of the solar cell that extends in the second direction, and a length in the first direction is equal to or shorter than a length of the solar cell that extends in the first direction.
